(19) United States
(12) Patent Application Publication
(10) Pub. No.: US 2025/0219629 A1
(43) Pub. Date: Jul. 3, 2025

(54) INTER-LANE SKEW COMPENSATION METHOD

(71) Applicant: MEDIATEK INC., Hsinchu City (TW)

(72) Inventors: Chih-Lun Chuang, Hsinchu City (TW); Pin-Yang Huang, Hsinchu City (TW)

(73) Assignee: MEDIATEK INC., Hsinchu City (TW)

(21) Appl. No.: 19/002,746

(22) Filed: Dec. 27, 2024

Related U.S. Application Data
(60) Provisional application No. 63/614,953, filed on Dec. 27, 2023.

(51) Int. Cl. H03K 5/15; H03K 3/037; H03K 5/00

(52) U.S. Cl. CPC H03K 5/15; H03K 3/037; H03K 2005/00234

(57) ABSTRACT

The present invention provides a circuitry including a first sampling circuit and a second sampling circuit. The first sampling circuit is configured to use a first clock signal to sample first data to generate sampled first data to a plurality of first lanes of a transmitter via a plurality of first connection lines. The second sampling circuit is configured to use a second clock signal to sample second data to generate sampled second data to a plurality of second lanes of the transmitter via a plurality of second connection lines. Lengths of the plurality of second connection lines are longer than lengths of the plurality of first connection lines, and delay amount of the second clock signal is less than delay amount of the first clock signal.

### CROSS REFERENCE TO RELATED APPLICATIONS

This application claims the benefit of U.S. Provisional Application No. 63/614,953, filed on Dec. 27, 2023. The content of the application is incorporated herein by reference.

### BACKGROUND

A die-to-die interface provides a seamless connection between the internal interconnect fabric on two dies, and the die-to-die interface is generally implemented by using a high-speed serializer/deserializer (SerDes) architecture or high-density parallel architecture, which are optimized to support multiple advanced 2D, 2.5D, and 3D packaging technologies. In order to increase the die-to-die link bandwidth efficiency, a macro within the die-to-die interface becomes deep and narrow, and a high die edge bandwidth density or a high area bandwidth density is required in the interface design. However, the design choices aimed at increasing die-to-die link bandwidth efficiency may lead to significant differences in routing lengths for lanes in various areas of the interface, resulting in increased inter-lane skew during high-speed operation.

### SUMMARY

It is therefore an objective of the present invention to provide a circuitry for a die-to-die interface that offers improved inter-lane skew compensation, to solve the above-mentioned problems.

According to one embodiment of the present invention, a circuitry comprising a first sampling circuit and a second sampling circuit is disclosed. The first sampling circuit is configured to use a first clock signal to sample first data to generate sampled first data to a plurality of first lanes of a transmitter via a plurality of first connection lines. The second sampling circuit is configured to use a second clock signal to sample second data to generate sampled second data to a plurality of second lanes of the transmitter via a plurality of second connection lines. Lengths of the plurality of second connection lines are longer than lengths of the plurality of first connection lines, and delay amount of the second clock signal is less than delay amount of the first clock signal.

According to one embodiment of the present invention, a circuitry comprising a first sampling circuit and a second sampling circuit is disclosed. The first sampling circuit is configured to use a first clock signal to sample first data to generate sampled first data, wherein the first data is received from a plurality of first lanes of a receiver via a plurality of first connection lines. The second sampling circuit is configured to use a second clock signal to sample second data to generate sampled second data, wherein the second data is received from a plurality of second lanes of the receiver via a plurality of second connection lines. Lengths of the plurality of second connection lines are longer than lengths of the plurality of first connection lines, and delay amount of the second clock signal is greater than delay amount of the first clock signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a circuitry of a physical layer of a die according to one embodiment of the present invention.

FIG. 2 is a diagram illustrating a circuit within the AD/DA interface according to one embodiment of the present invention.

FIG. 3 is a diagram illustrating a circuit within the AD/DA interface according to one embodiment of the present invention.

FIG. 4 is a diagram illustrating a circuit within the AD/DA interface according to one embodiment of the present invention.

FIG. 5 is a diagram illustrating a clock signal generator according to one embodiment of the present invention.

FIG. 6 is a timing diagram of the signals related to the embodiments shown in FIG. 2-FIG. 5.

FIG. 7 is a timing diagram of the signals according to one embodiment of the present invention.

FIG. 8 is a diagram illustrating a circuit within the AD/DA interface according to one embodiment of the present invention.

FIG. 9 is a diagram illustrating a circuit within the AD/DA interface according to one embodiment of the present invention.

FIG. 10 is a diagram illustrating a clock signal generator according to one embodiment of the present invention.

FIG. 11 is a timing diagram of the signals related to the embodiments shown in FIG. 8-FIG. 10.

FIG. 12 is a timing diagram of the signals according to one embodiment of the present invention.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. The terms “couple” and “couples” are intended to mean either an indirect or a direct electrical connection. Thus, if a first device couples to a second device, that connection may be through a direct electrical connection, or through an indirect electrical connection via other devices and connections.

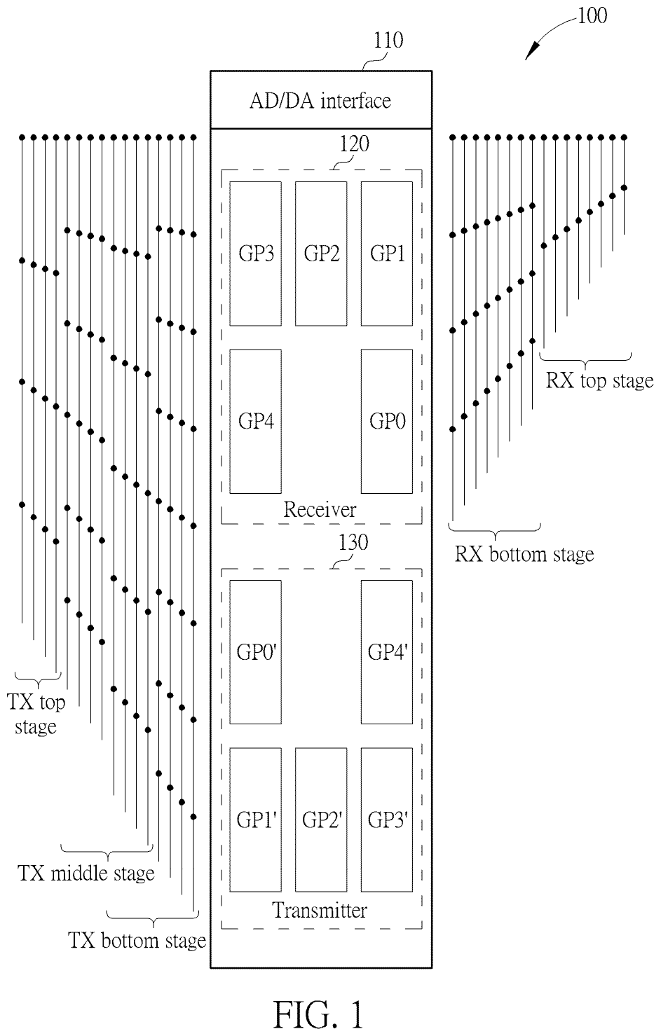

FIG. 1 is a diagram illustrating a circuitry 100 of a physical layer of a die according to one embodiment of the present invention. As shown in FIG. 1, the circuitry 100 comprises an analog-to-digital (AD) and digital-to-analog (DA)) interface 110, a receiver 120 and a transmitter 130, wherein the receiver 120 comprises a plurality of groups of lanes such as GP0-GP4, and each of the groups GP0-GP1 comprises a plurality of lanes such as sixteen lanes; and the transmitter 130 comprises a plurality of groups of lanes such as GP0′-GP4′, and each of the groups GP0′-GP1′ comprises a plurality of lanes such as sixteen lanes. In this embodiment, the circuitry 100 is positioned at the edge of the die, and the circuitry 100 is configured to communicate with another die via a die-to-die interface, wherein the die comprising the circuitry 100 and the other die can be manufactured within a package, and the die may satisfy any suitable specification for a die-to-die interconnect, such as Universal Chiplet Interconnect Express (UCIe).

The circuitry 100 also comprises a plurality of connection lines that are used to connect the AD/DA interface 110 and each of the lanes of the receiver 120 and the transmitter 130, wherein the connection lines are implemented by at least one metal layer in the semiconductor process. Since each lane has a different depth in the chip, these connection lines have different lengths. In the embodiment shown in FIG. 1, the connection lines for connecting the AD/DA interface 110 and the lanes of the transmitter 130 are divided into three stages, wherein the connection lines in a top stage have shorter lengths, the connection lines in a middle stage have middle lengths, and the connection lines in a bottom stage have longest lengths. Similarly, the connection lines for connecting the AD/DA interface 110 and the lanes of the receiver 120 are divided into two stages, wherein the connection lines in a top stage have shorter lengths, and the connection lines in a bottom stage have longest lengths. As described in the background of the present invention, a macro within the die-to-die interface becomes deep and narrow, so different stage of connection lines may have very different lengths, resulting in worse inter-lane skew in the high speed operation. To solve the inter-lane skew problem, the embodiment provides a circuit design and related timing control to minimize inter-lane skew without excessively increasing power consumption and chip area.

It is noted that the number of stages of connection lines shown in FIG. 1 is or illustrative purposes only and does not limit the present invention.

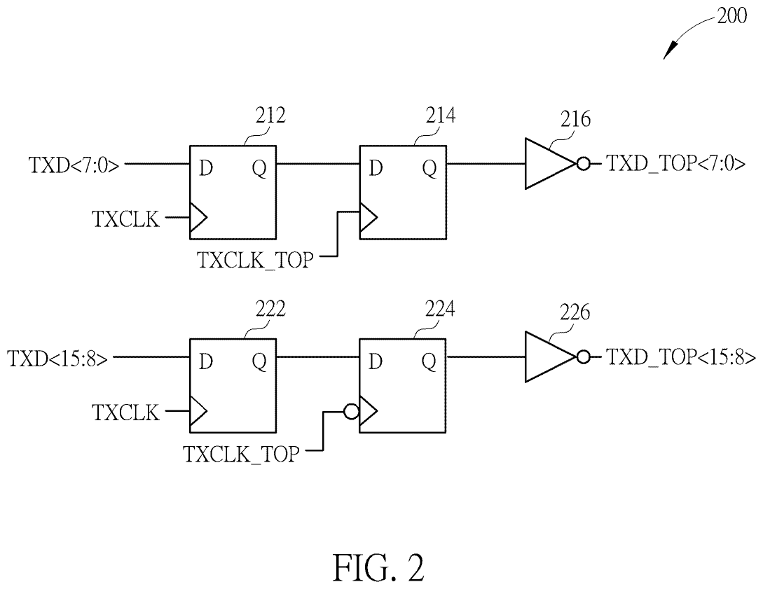

FIG. 2 is a diagram illustrating a sampling circuit 200 within the AD/DA interface 110 according to one embodiment of the present invention, wherein the sampling circuit 200 is configured to output the transmission data generated by the AD/DA interface 110 to part of the transmitter 130 via the connection lines of the top stage. In this embodiment, it is assumed that the AD/DA interface 110 generates the transmission data with 16 bits, but it's not a limitation of the present invention. As shown in FIG. 2, the sampling circuit 200 comprises flip-flops 212 214, 222 and 224, and inverters 216 and 226. The flip-flops 212, 214 and the inverter 216 are used to sample the most-significant bits (MSBs) of the transmission data TXD<7:0> to generate the data TXD_TOP<7:0> to the part of the transmitter 130 via the connection lines corresponding to the top stage. Specifically, the flip-flop 212 uses a clock signal TXCLK to sample the transmission data TXD<7:0>, and the flip-flop 214 uses a rising edge of a clock signal TXCLK_TOP to sample a signal outputted by the flip-flop 212, and the inverter 216 processes a signal outputted by the flip-flop 214 to generate the data TXD_TOP<7:0>. In addition, The flip-flops 222, 224 and the inverter 226 are used to sample the least-significant bits (LSBs) of the transmission data TXD<15:8> to generate the data TXD_TOP<15:8> to the part of the transmitter 130 via the connection lines corresponding to the top stage. Specifically, the flip-flop 222 uses the clock signal TXCLK to sample the transmission data TXD<15:8>, and the flip-flop 224 uses a falling edge of the clock signal TXCLK_TOP to sample a signal outputted by the flip-flop 222, and the inverter 226 processes a signal outputted by the flip-flop 224 to generate the data TXD_TOP<15:8>. In this embodiment, the clock signal TXCLK_TOP is generated by greatly delaying the clock signal TXCLK, that is the clock signal TXCLK_TOP can be regarded as having large clock skew.

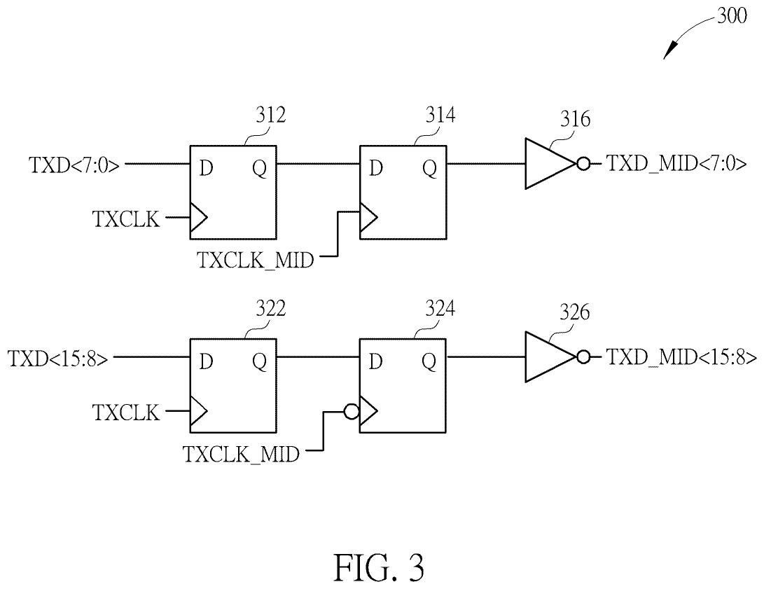

FIG. 3 is a diagram illustrating a sampling circuit 300 within the AD/DA interface 110 according to one embodiment of the present invention, wherein the sampling circuit 300 is configured to output the transmission data generated by the AD/DA interface 110 to part of the transmitter 130 via the connection lines of the middle stage. In this embodiment, it is assumed that the AD/DA interface 110 generates the transmission data with 16 bits, but it's not a limitation of the present invention. As shown in FIG. 3, the sampling circuit 300 comprises flip-flops 312 314, 322 and 324, and inverters 316 and 326. The flip-flops 312, 314 and the inverter 316 are used to sample the MSBs of the transmission data TXD<7:0> to generate the data TXD_MID<7:0> to the part of the transmitter 130 via the connection lines corresponding to the middle stage. Specifically, the flip-flop 312 uses the clock signal TXCLK to sample the transmission data TXD<7:0>, and the flip-flop 314 uses a rising edge of a clock signal TXCLK_MID to sample a signal outputted by the flip-flop 312, and the inverter 316 processes a signal outputted by the flip-flop 314 to generate the data TXD_MID<7:0>. In addition, The flip-flops 322, 324 and the inverter 326 are used to sample the LSBs of the transmission data TXD<15:8> to generate the data TXD_MID<15:8> to the part of the transmitter 130 via the connection lines corresponding to the middle stage. Specifically, the flip-flop 322 uses the clock signal TXCLK to sample the transmission data TXD<15:8>, and the flip-flop 324 uses a falling edge of the clock signal TXCLK_MID to sample a signal outputted by the flip-flop 322, and the inverter 326 processes a signal outputted by the flip-flop 324 to generate the data TXD_MID<15:8>. In this embodiment, the clock signal TXCLK_MID is generated by delaying the clock signal TXCLK, that is the clock signal TXCLK_TOP can be regarded as having clock skew. In this embodiment, the delay amount of the clock signal TXCLK_MID is less than the delay amount of the clock signal TXCLK_TOP.

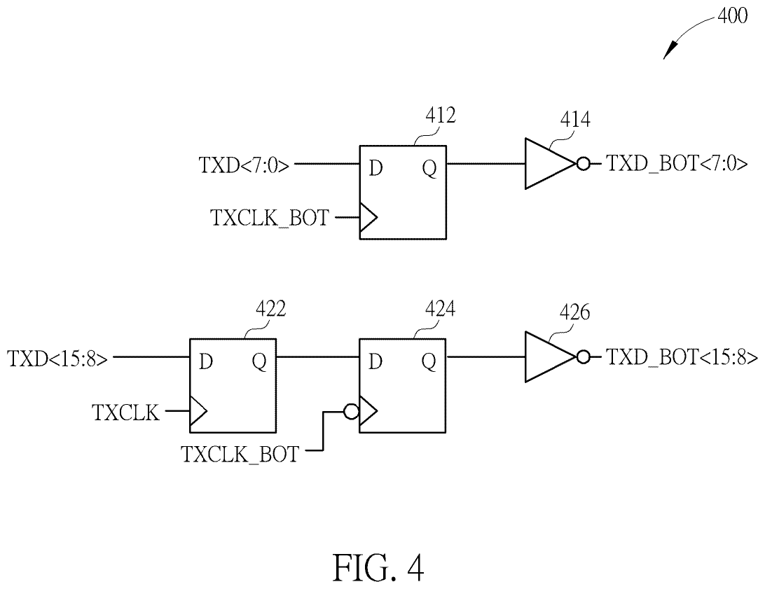

FIG. 4 is a diagram illustrating a sampling circuit 400 within the AD/DA interface 110 according to one embodiment of the present invention, wherein the sampling circuit 400 is configured to output the transmission data generated by the AD/DA interface 110 to part of the transmitter 130 via the connection lines of the bottom stage. In this embodiment, it is assumed that the AD/DA interface 110 generates the transmission data with 16 bits, but it's not a limitation of the present invention. As shown in FIG. 4, the sampling circuit 400 comprises flip-flops 412, 422 and 424, and inverters 414 and 426. The flip-flops 412 and the inverter 414 are used to sample the MSBs of the transmission data TXD<7:0> to generate the data TXD_BOT<7:0> to the part of the transmitter 130 via the connection lines corresponding to the bottom stage. Specifically, the flip-flop 412 uses a rising edge of a clock signal TXCLK_BOT to sample the transmission data TXD<7:0>, and the inverter 414 processes a signal outputted by the flip-flop 412 to generate the data TXD_BOT<7:0>. In addition, The flip-flops 422, 424 and the inverter 426 are used to sample the LSBs of the transmission data TXD<15:8> to generate the data TXD_BOT<15:8> to the part of the transmitter 130 via the connection lines corresponding to the bottom stage. Specifically, the flip-flop 422 uses the clock signal TXCLK to sample the transmission data TXD<15:8>, and the flip-flop 424 uses a falling edge of the clock signal TXCLK_MID to sample a signal outputted by the flip-flop 422, and the inverter 426 processes a signal outputted by the flip-flop 424 to generate the data TXD_BOT<15:8>. In this embodiment, the clock signal TXCLK_BOT is generated by slightly delaying the clock signal TXCLK, or the clock signal TXCLK can directly serve as the clock signal TXCLK_BOT. In this embodiment, the delay amount of the clock signal TXCLK_BOT is less than the delay amount of the clock signal TXCLK_MID, and the delay amount of the clock signal TXCLK_MID is less than the delay amount of the clock signal TXCLK_TOP.

In the embodiment shown in FIG. 2-FIG. 4, because the sampling circuit 200 uses the clock signal TXCLK TOP with large delay amount to output the data TXD TOP<15:0> to the lanes of the transmitter 130 via the shorter connection lines in the top stage, the sampling circuit 300 uses the clock signal TXCLK_MID with middle delay amount to output the data TXD_MID<15:0> to the lanes of the transmitter 130 via the medium-length connection lines in the middle stage, and the sampling circuit 400 uses the clock signal TXCLK_BOT with smallest delay amount to output the data TXD_BOT<15:0> to the lanes of the transmitter 130 via the longest connection lines, the times when data is sent to the plurality of lanes of the transmitter 130 will be very close, so the circuitry 100 will not suffer serious inter-lane skew described in the background of the present invention. In addition, because the data transmitted to the plurality of lanes of the transmitter 130 are aligned by using the clock signals TXCLK_TOP, TXCLK_MID and TXCLK_BOT with different delay amount to sample the data TXD<15:0>, these is no need to position many buffers on the connection lines to compensate the inter-lane skew, so the circuitry 100 will not increase too much power consumption and chip area, and this circuit design will be robust to process, voltage and temperature (PVT) variation.

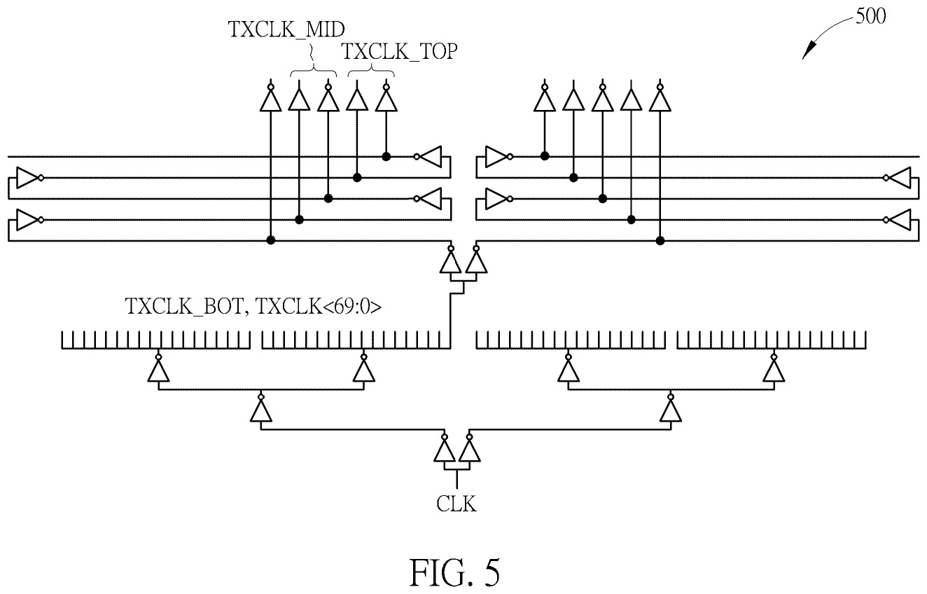

FIG. 5 is a diagram illustrating a clock signal generator 500 according to one embodiment of the present invention. As shown in FIG. 5, the clock signal generator 500 has a H-tree type and a snake routing, wherein the clock signal generator 500 generates clock signals TXCLK and TXCLK_BOT by delaying a root clock signal CLK, and the clock signal TXCLK passes through the snake routing to generate the clock signals TXCLK_MID and TXCLK_TOP. In this embodiment, the style of the snake routing shown in FIG. 5 and the style of the connection lines shown in FIG. 1 are similar. For example, the snake routing and the connection lines may be implemented by using the same metal layer, and the snake routing and the connection lines have similar length (i.e., the routing length from TXCLK to TXCLK_MID is similar to the length of the connection lines corresponding to the middle stage, and the routing length from TXCLK to TXCLK_TOP is similar to the length of the connection lines corresponding to the top stage).

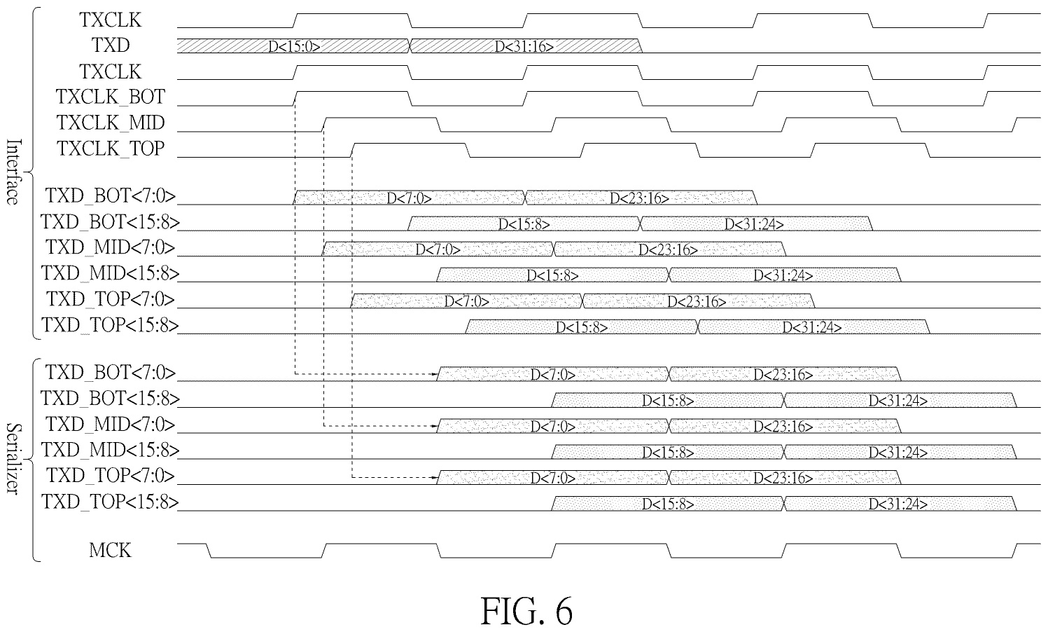

FIG. 6 is a timing diagram of the signals related to the embodiments shown in FIG. 2-FIG. 5, wherein the upper portion shows the timing diagram of the signals corresponding to the AD/DA interface 110, the lower portion shows the timing diagram of the signals corresponding a serializer (not shown) used to output the data to the another die, and “MCK” in the figure represents a clock signal used by the serializer.

In the above embodiment shown in FIG. 2-FIG. 6, by using the rising edge of the clock signal TXCLK_TOP/TXCLK_MID/TXCLK_BOT to sample the signal to generate the MSBs of the data, and using the falling edge of the clock signal TXCLK_TOP/TXCLK_MID/TXCLK_BOT to sample the signal to generate the LSBs of the data, the intra-lane skew between the signals within one group can be improved, the crosstalk can be minimized, and the dynamic IR drop can be improved.

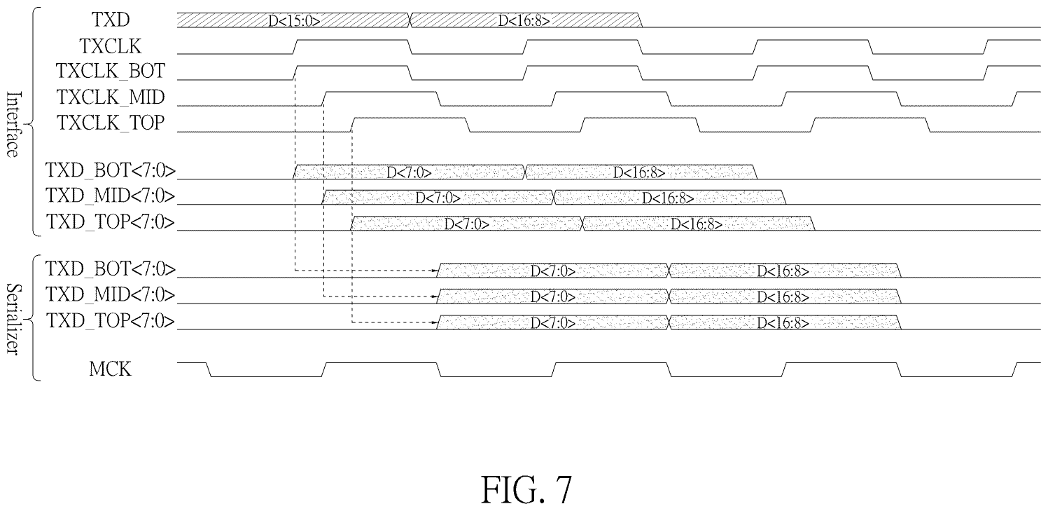

In one embodiment, if the AD/DA interface 110 generates the transmission data with lower bits such as 8 bits, the sampling circuit 200 may be modified to remove the flip-flops 222, 224 and the inverter 226, the sampling circuit 300 may be modified to remove the flip-flops 322, 324 and the inverter 326, and the sampling circuit 400 may be modified to remove the flip-flops 422, 424 and the inverter 426, and the timing diagram of the signals of this embodiment is shown in FIG. 7.

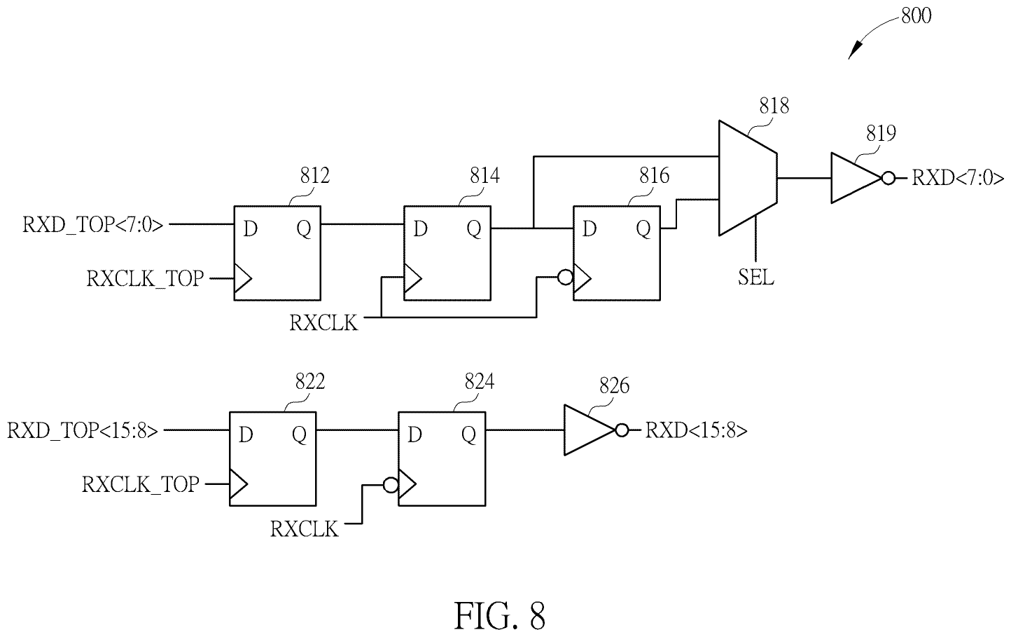

FIG. 8 is a diagram illustrating a sampling circuit 800 within the AD/DA interface 110 according to one embodiment of the present invention, wherein the circuit 800 is configured to receive data from the receiver 120 via the connection lines of the top stage. In this embodiment, it is assumed that the AD/DA interface 110 receives the data with 16 bits, but it's not a limitation of the present invention. As shown in FIG. 8, the sampling circuit 800 comprises flip-flops 812, 814, 816, 822, 824, a multiplexer 818, and inverters 819 and 826. The flip-flops 812, 814, 816, the multiplexer 818 and the inverter 819 are used to sample the MSBs of the received data RXD_TOP<7:0> from connection lines corresponding to the top stage to generate the data RXD<7:0>. Specifically, the flip-flop 812 uses a clock signal RXCLK_TOP to sample the received data RXD_TOP<7:0>, the flip-flop 814 uses a rising edge of a clock signal RXCLK to sample a signal outputted by the flip-flop 812, the flip-flop 816 uses a falling edge of the clock signal RXCLK to sample a signal outputted by the flip-flop 814, the multiplexer 818 selects one of the signals outputted by the flip-flips 814 and 816 according to a selection signal SEL (in this embodiment, the upper signal is selected), and the inverter 819 processes a signal outputted by the multiplexer 818 to generate the data RXD<7:0>. In addition, the flip-flops 822, 824 and the inverter 826 are used to sample the LSBs of the received data RXD_TOP<15:8> from connection lines corresponding to the top stage to generate the data RXD<15:8>. Specifically, the flip-flop 822 uses the clock signal RXCLK_TOP to sample the received data RXD_TOP<7:0>, the flip-flop 824 uses a falling edge of the clock signal RXCLK to sample a signal outputted by the flip-flop 822, and the inverter 826 processes a signal outputted by the flip-flop 824 to generate the data RXD<15:8>. In this embodiment, both the clock signal RXCLK_TOP and the clock signal RXCLK are generated by a root clock signal, and the delay amount of the clock signal RXCLK is higher than the delay amount of the clock signal RXCLK_TOP, that is the clock signal RXCLK can be regarded as having large clock skew than the clock signal RXCLK_TOP.

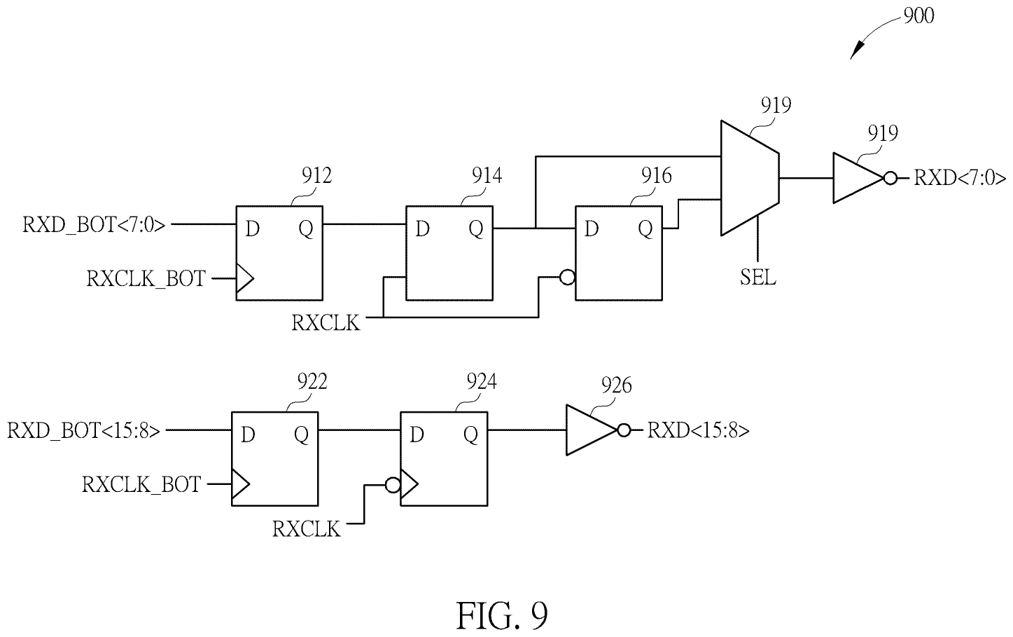

FIG. 9 is a diagram illustrating a sampling circuit 900 within the AD/DA interface 110 according to one embodiment of the present invention, wherein the sampling circuit 900 is configured to receive data from the receiver 120 via the connection lines of the bottom stage. In this embodiment, it is assumed that the AD/DA interface 110 receives the data with 16 bits, but it's not a limitation of the present invention. As shown in FIG. 9, the sampling circuit 900 comprises flip-flops 912, 914, 916, 922, 924, a multiplexer 918, and inverters 919 and 926. The flip-flops 912, 914, 916, the multiplexer 918 and the inverter 919 are used to sample the MSBs of the received data RXD_BOT<7:0> from connection lines corresponding to the top stage to generate the data RXD<7:0>. Specifically, the flip-flop 912 uses a clock signal RXCLK_BOT to sample the received data RXD_BOT<7:0>, the flip-flop 914 uses a rising edge of a clock signal RXCLK to sample a signal outputted by the flip-flop 912, the flip-flop 916 uses a falling edge of the clock signal RXCLK to sample a signal outputted by the flip-flop 914, the multiplexer 918 selects one of the signals outputted by the flip-flips 914 and 916 according to a selection signal SEL (in this embodiment, the upper signal is selected), and the inverter 919 processes a signal outputted by the multiplexer 918 to generate the data RXD<7:0>. In addition, the flip-flops 922, 924 and the inverter 926 are used to sample the LSBs of the received data RXD_BOT<15:8> from connection lines corresponding to the top stage to generate the data RXD<15:8>. Specifically, the flip-flop 922 uses the clock signal RXCLK_BOT to sample the received data RXD_BOT<7:0>, the flip-flop 924 uses a falling edge of the clock signal RXCLK to sample a signal outputted by the flip-flop 922, and the inverter 926 processes a signal outputted by the flip-flop 924 to generate the data RXD<15:8>. In this embodiment, all the clock signals RXCLK_BOT, RXCLK_TOP and RXCLK are generated by a root clock signal, the delay amount of the clock signal RXCLK is higher than the delay amount of the clock signal RXCLK_BOT, and the delay amount of the clock signal RXCLK_BOT is higher than the delay amount of the clock signal RXCLK_TOP, that is, the clock signal RXCLK can be regarded as having largest clock skew, the clock signal RXCLK_TOP can be regarded as having smallest clock skew.

In the embodiment shown in FIG. 8 and FIG. 9, because the sampling circuit 800 uses the clock signal TXCLK_TOP with smallest delay amount and the clock signal RXCLK with the largest delay amount to sample the data from the connection lines corresponding to the top stage to generate the data RXD<15:0>, and the sampling circuit 900 uses the clock signal TXCLK_BOT with medium delay amount and the clock signal RXCLK with the largest delay amount to sample the data from the connection lines corresponding to the bottom stage to generate the data RXD<15:0>, the times when the data RXD<15:0> from the plurality of lanes of the receiver 120 will be very close, so the circuitry 100 will not suffer serious inter-lane skew described in the background of the present invention. In addition, because the data RXD_TOP<15:0> and RXD_BOT<15:0> from the plurality of lanes of the receiver 120 are sampled and aligned by using the clock signals RXCLK_TOP, RXCLK_BOT and RXCLK with different delay amount, these is no need to position many buffers on the connection lines to compensate the inter-lane skew, so the circuitry 100 will not increase too much power consumption and chip area, and this circuit design will be robust to PVT variation.

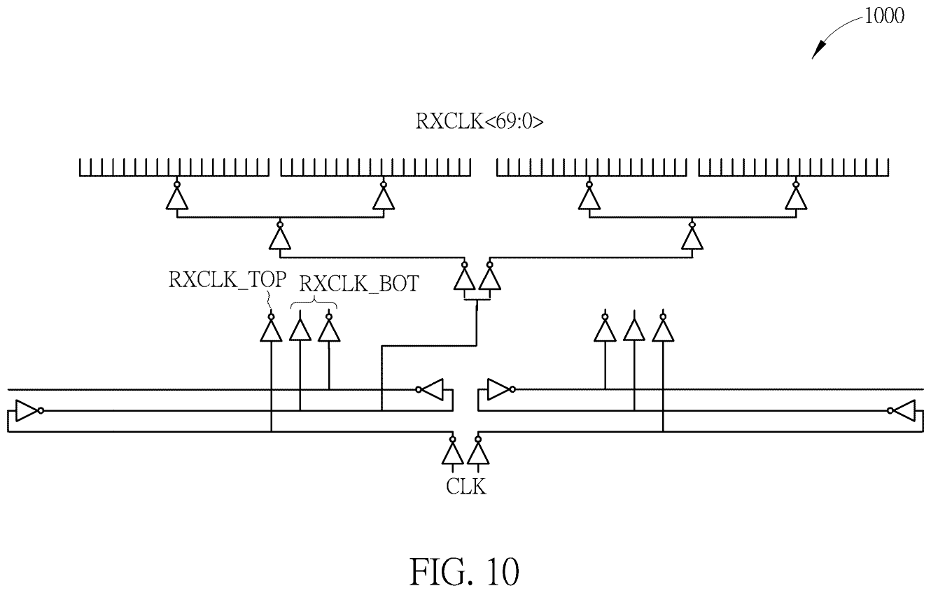

FIG. 10 is a diagram illustrating a clock signal generator 1000 according to one embodiment of the present invention. As shown in FIG. 10, the clock signal generator 1000 has a H-tree type and a snake routing, wherein the clock signal generator 1000 generates clock signals RXCLK_BOT and RXCLK_BOT by delaying a root clock signal CLK, and the clock signal RXCLK_BOT passes through the snake routing to generate the clock signal RXCLK. In this embodiment, the style of the snake routing shown in FIG. 10 and the style of the connection lines shown in FIG. 1 are similar. For example, the snake routing and the connection lines may be implemented by using the same metal layer, and the snake routing and the connection lines have similar length (i.e., the routing length from CLK to RXCLK_TOP is similar to the length of the connection lines corresponding to the top stage, the routing length from CLK to RXCLK_BOT is similar to the length of the connection lines corresponding to the bottom stage.

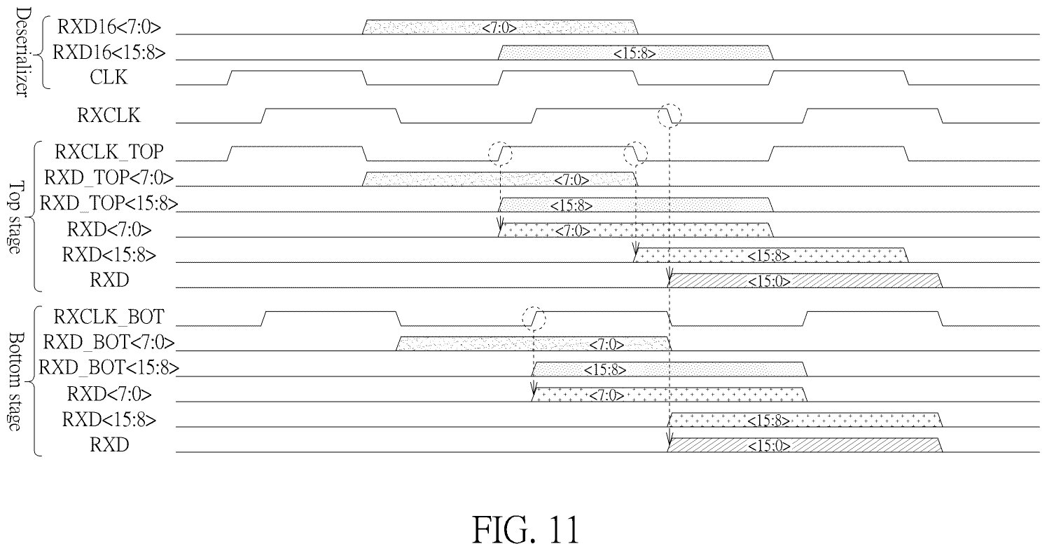

FIG. 11 is a timing diagram of the signals related to the embodiments shown in FIG. 8-FIG. 10, wherein the upper portion shows the timing diagram of the signals from a deserializer (not shown) to the AD/DA interface 110 (the symbol RXD16<7:0> and RXD16<15:8> are the received data), the middle portion shows the timing diagram of the signals within the AD/DA interface 110 corresponding to the top stage, and the lower portion shows the timing diagram of the signals within the AD/DA interface 110 corresponding to the bottom stage.

In the above embodiment shown in FIG. 8-FIG. 11, by using the sampling mechanism to sample the received data, the intra-lane skew between the signals within one group can be improved, the crosstalk can be minimized, and the dynamic IR drop can be improved.

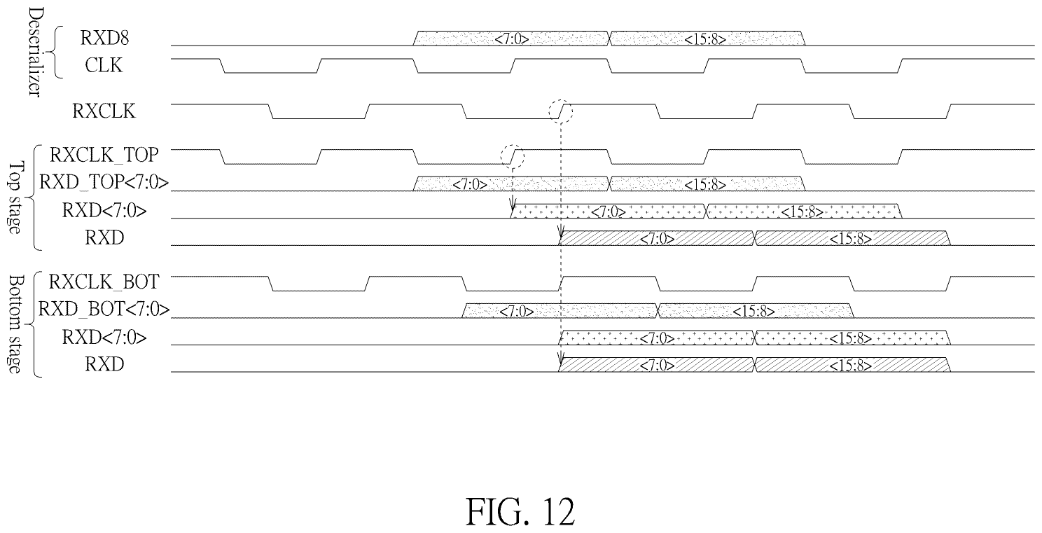

In one embodiment, if the AD/DA interface 110 generates the transmission data with lower bits such as 8 bits, the sampling circuit 800 may be modified to remove the flip-flops 822, 824 and the inverter 826, the sampling circuit 900 may be modified to remove the flip-flops 922, 924 and the inverter 926, and the timing diagram of the signals of this embodiment is shown in FIG. 12.

Briefly summarized, in the embodiments of the present invention, by using clock signals within different delay amount (different clock skew) to generate the data to a plurality of lanes via different lengths of connection lines, and/or using clock signals within different delay amount to sample the data from a plurality of lanes corresponding different lengths of connection lines, the AD/DA interface will not suffer serious inter-lane skew described in the background of the present invention, and this circuit design will be robust to PVT variation. In addition, in order to generate the clock signals with suitable phases, the clock signals are generated by using snake routing having similar style to the connection lines connected between the transmitter/receiver and the AD/DA interface, and the delay amount of each of the clock signals for generating the transmission data or sampling the received data is determined based on the corresponding length of the connection lines.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A circuitry, comprising:
a first sampling circuit, configured to use a first clock signal to sample first data to generate sampled first data to a plurality of first lanes of a transmitter via a plurality of first connection lines; and
a second sampling circuit, configured to use a second clock signal to sample second data to generate sampled second data to a plurality of second lanes of the transmitter via a plurality of second connection lines;
wherein lengths of the plurality of second connection lines are longer than lengths of the plurality of first connection lines, and delay amount of the second clock signal is less than delay amount of the first clock signal.

2. The circuitry of claim 1, wherein the first sampling circuit comprises:
a first flip-flop, configured to use a clock signal to sample the first data; and
a second flip-flop, configured to use the first clock signal to sample a signal outputted by the first flip-flop to generate the sampled first data; and
the second sampling circuit comprises:
a third flip-flop, configured to use the clock signal to sample the second data; and
a fourth flip-flop, configured to use the second clock signal to sample a signal outputted by the third flip-flop to generate the sampled second data.

3. The circuitry of claim 1, wherein the first sampling circuit comprises:
a first flip-flop, configured to use a clock signal to sample a portion of the first data;
a second flip-flop, configured to use a rising edge of the first clock signal to sample a signal outputted by the first flip-flop to generate a portion of the sampled first data;
a third flip-flop, configured to use the clock signal to sample another portion of the first data; and
a fourth flip-flop, configured to use a falling edge of the first clock signal to sample a signal outputted by the third flip-flop to generate another portion of the sampled first data; and
the second sampling circuit comprises:
a fifth flip-flop, configured to use the clock signal to sample a portion of the second data;
a sixth flip-flop, configured to use a rising edge of the second clock signal to sample a signal outputted by the fifth flip-flop to generate a portion of the sampled second data;
a seventh flip-flop, configured to use the clock signal to sample another portion of the second data; and
an eighth flip-flop, configured to use a falling edge of the second clock signal to sample a signal outputted by the seventh flip-flop to generate another portion of the sampled second data.

4. The circuitry of claim 1, further comprising:
a clock signal generator, configured to use a snake routing to delay a clock signal to generate the first clock signal and the second clock signal, wherein the snake routing, the plurality of first connection lines and the plurality of second connection lines are implemented by using a same metal layer, a routing length from the clock signal to the first clock signal correspond to a length of the plurality of first connection lines, and a routing length from the clock signal to the second clock signal correspond to a length of the plurality of second connection lines.

5. The circuitry of claim 1, further comprising:
a third sampling circuit, configured to use a third clock signal to sample third data to generate sampled third data to a plurality of third lanes of the transmitter via a plurality of third connection lines;
wherein lengths of the plurality of third connection lines are longer than the lengths of the plurality of second connection lines, and delay amount of the third clock signal is less than the delay amount of the second clock signal.

6. The circuitry of claim 1, wherein the first sampling circuit comprises:
a first flip-flop, configured to use a clock signal to sample the first data; and
a second flip-flop, configured to use the first clock signal to sample a signal outputted by the first flip-flop to generate the sampled first data; and
the second sampling circuit comprises:
a third flip-flop, configured to use the clock signal to sample the second data; and
a fourth flip-flop, configured to use the second clock signal to sample a signal outputted by the third flip-flop to generate the sampled second data; and
the third sampling circuit comprises:
a fifth flip-flop, configured to use the third clock signal to sample the third data to generate the sampled third data.

7. The circuitry of claim 5, further comprising:
a clock signal generator, configured to use a snake routing to delay a clock signal to generate the first clock signal, the second clock signal and the third clock signal, wherein the snake routing, the plurality of first connection lines, the plurality of second connection lines and the plurality of third connection lines are implemented by using a same metal layer, a routing length from the clock signal to the first clock signal correspond to a length of the plurality of first connection lines, a routing length from the clock signal to the second clock signal correspond to a length of the plurality of second connection lines, and a routing length from the clock signal to the third clock signal correspond to a length of the plurality of third connection lines.

8. The circuitry of claim 1, further comprising:
a third sampling circuit, configured to use a third clock signal to sample third data to generate sampled third data, wherein the third data is received from a plurality of third lanes of a receiver via a plurality of third connection lines; and
a fourth sampling circuit, configured to use a fourth clock signal to sample fourth data to generate sampled fourth data, wherein the fourth data is received from a plurality of fourth lanes of the receiver via a plurality of fourth connection lines;
wherein lengths of the plurality of fourth connection lines are longer than lengths of the plurality of third connection lines, and delay amount of the fourth clock signal is greater than delay amount of the third clock signal.

9. The circuitry of claim 8, wherein the third sampling circuit comprises:
a first flip-flop, configured to use the third clock signal to sample the third data; and
a second flip-flop, configured to use a clock signal to sample a signal outputted by the first flip-flop to generate the sampled third data; and
the fourth sampling circuit comprises:
a third flip-flop, configured to use the fourth clock signal to sample the fourth data; and
a fourth flip-flop, configured to use the clock signal to sample a signal outputted by the third flip-flop to generate the sampled fourth data.

10. The circuitry of claim 8, wherein the third sampling circuit comprises:
a first flip-flop, configured to use the third clock signal to sample a portion of the third data; and
a second flip-flop, configured to use a rising edge of a clock signal to sample a signal outputted by the first flip-flop to generate a portion of the sampled third data;
a third flip-flop, configured to use the third clock signal to sample another portion of the third data; and
a fourth flip-flop, configured to use a falling edge of the third clock signal to sample a signal outputted by the third flip-flop to generate another portion of the sampled third data; and
the fourth sampling circuit comprises:
a fifth flip-flop, configured to use the fourth clock signal to sample a portion of the fourth data; and
a sixth flip-flop, configured to use the rising edge of the clock signal to sample a signal outputted by the fifth flip-flop to generate a portion of the sampled fourth data;
a seventh flip-flop, configured to use the fourth clock signal to sample another portion of the fourth data; and
an eighth flip-flop, configured to use the falling edge of the fourth clock signal to sample a signal outputted by the seventh flip-flop to generate another portion of the sampled fourth data.

11. The circuitry of claim 8, further comprising:
a clock signal generator, configured to use a snake routing to delay a clock signal to generate the third clock signal and the fourth clock signal, wherein the snake routing, the plurality of third connection lines and the plurality of fourth connection lines are implemented by using a same metal layer, a routing length from the clock signal to the third clock signal correspond to a length of the plurality of third connection lines, and a routing length from the clock signal to the fourth clock signal correspond to a length of the plurality of fourth connection lines.

12. A circuitry, comprising:
a first sampling circuit, configured to use a first clock signal to sample first data to generate sampled first data, wherein the first data is received from a plurality of first lanes of a receiver via a plurality of first connection lines; and
a second sampling circuit, configured to use a second clock signal to sample second data to generate sampled second data, wherein the second data is received from a plurality of second lanes of the receiver via a plurality of second connection lines;
wherein lengths of the plurality of second connection lines are longer than lengths of the plurality of first connection lines, and delay amount of the second clock signal is greater than delay amount of the first clock signal.

13. The circuitry of claim 12, wherein the first sampling circuit comprises:
a first flip-flop, configured to use the first clock signal to sample the first data; and
a second flip-flop, configured to use a clock signal to sample a signal outputted by the first flip-flop to generate the sampled first data; and
the second sampling circuit comprises:
a third flip-flop, configured to use the second clock signal to sample the second data; and
a fourth flip-flop, configured to use the clock signal to sample a signal outputted by the third flip-flop to generate the sampled second data.

14. The circuitry of claim 12, wherein the first sampling circuit comprises:
a first flip-flop, configured to use the first clock signal to sample a portion of the first data; and
a second flip-flop, configured to use a rising edge of a clock signal to sample a signal outputted by the first flip-flop to generate a portion of the sampled first data;
a third flip-flop, configured to use the first clock signal to sample another portion of the first data; and
a fourth flip-flop, configured to use a falling edge of the first clock signal to sample a signal outputted by the third flip-flop to generate another portion of the sampled first data; and
the second sampling circuit comprises:
a fifth flip-flop, configured to use the second clock signal to sample a portion of the second data; and
a sixth flip-flop, configured to use the rising edge of the clock signal to sample a signal outputted by the fifth flip-flop to generate a portion of the sampled second data;
a seventh flip-flop, configured to use the second clock signal to sample another portion of the second data; and
an eighth flip-flop, configured to use the falling edge of the second clock signal to sample a signal outputted by the seventh flip-flop to generate another portion of the sampled second data.

15. The circuitry of claim 12, further comprising:
a clock signal generator, configured to use a snake routing to delay a clock signal to generate the first clock signal and the second clock signal, wherein the snake routing, the plurality of first connection lines and the plurality of second connection lines are implemented by using a same metal layer, a routing length from the clock signal to the first clock signal correspond to a length of the plurality of first connection lines, and a routing length from the clock signal to the second clock signal correspond to a length of the plurality of second connection lines.
